(19) United States
(12) Patent Application Publication
(10) Pub. No.: US 2025/0372976 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/216,648

(22) Filed: May 22, 2025

(30) Foreign Application Priority Data
May 29, 2024 (JP) 2024-087305

(51) Int. Cl. H02G 3/08; B60R 16/023; H01R 25/16; H05K 7/20

(52) U.S. Cl. CPC H02G 3/081; B60R 16/0239; H01R 25/165; H05K 7/20518; H01R 2201/26

(57) ABSTRACT

An electrical connection unit includes a plurality of circuit constitution bodies and a support member that supports the plurality of circuit constitution bodies. Each of the circuit constitution bodies includes a plurality of electronic components, a bus bar that electrically connects the plurality of electronic components, and an insulating base member that holds the bus bar. In a case where a direction in which the plurality of electronic components and the base member face each other is a first direction, the base member has a facing region facing the plurality of electronic components when viewed from the first direction, and is fixed to the support member via a plurality of fixing portions that are separately disposed to surround an outer side of the facing region when viewed from the first direction.

### BACKGROUND OF THE INVENTION

### Field of the Invention

Embodiments of the present invention relate to an electrical connection unit.

Priority is claimed on Japanese Patent Application No. 2024-087305 filed in Japan on May 29, 2024, the content of which is incorporated herein by reference.

### Description of the Related Art

There is an electrical connection unit including a housing that accommodates electronic components and a bus bar attached to the housing in a standing posture.

### CITATION LIST

### Patent Document

Patent Document 1: Japanese Unexamined Patent Application, First Publication No. 2024-037492

### SUMMARY OF THE INVENTION

Incidentally, it is expected to improve thermal characteristics of an electrical connection unit.

An embodiment provides an electrical connection unit capable of improving thermal characteristics.

An electrical connection unit according to an embodiment includes a plurality of circuit constitution bodies and a support member that supports the plurality of circuit constitution bodies. Each of the circuit constitution bodies includes a plurality of electronic components, a bus bar that electrically connects the plurality of electronic components, and an insulating base member that holds the bus bar. In a case where a direction in which the plurality of electronic components and the base member face each other is a first direction, the base member has a facing region facing the plurality of electronic components when viewed from the first direction, and is fixed to the support member via a plurality of fixing portions that are separately disposed to surround an outer side of the facing region when viewed from the first direction.

According to one embodiment, the thermal characteristics of the electrical connection unit can be improved.

### BRIEF DESCRIPTION OF THE DRAWINGS

FIG. 1 is a cross-sectional view illustrating an electrical connection unit according to an embodiment;

FIG. 2 is a perspective view for describing a main body of the embodiment;

FIG. 3 is a perspective view for describing a subunit of the embodiment;

FIG. 4 is a partially exploded perspective view of the subunit of the embodiment;

FIG. 5 is a perspective view illustrating a routing board of the embodiment;

FIG. 6 is a partially exploded perspective view of the routing board according to the embodiment;

FIG. 7 is a plan view illustrating a routing board of the embodiment;

FIG. 8 is a partially exploded perspective view of the connection unit according to the embodiment;

FIG. 9 is a bottom view illustrating the routing board of the embodiment;

FIG. 10 is a cross-sectional view taken along line A-A of the structure illustrated in FIG. 7;

FIG. 11 is a cross-sectional view taken along line B-B of the structure illustrated in FIG. 7;

FIG. 12 is a cross-sectional view for describing a heat dissipation path related to a fixing portion of the embodiment;

FIG. 13 is a cross-sectional view for describing a heat dissipation path according to a modification example of the embodiment;

FIG. 14 is a cross-sectional view for describing an absorption structure for thermal expansion/contraction related to the fixing portion of the embodiment; and

FIG. 15 is a cross-sectional view showing an action of the absorption structure of the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

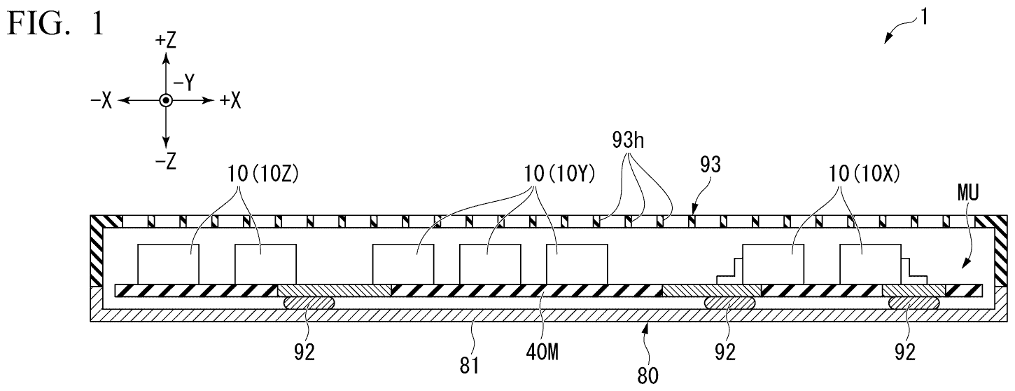

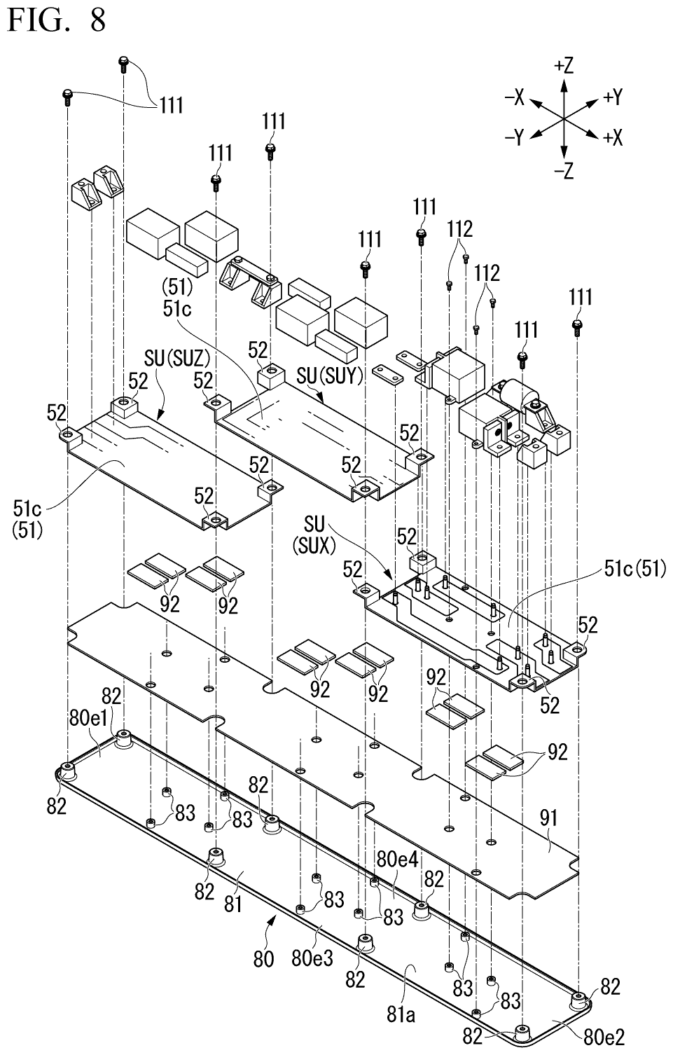

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 8). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 8). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### EMBODIMENT

### <1. Constitution of Electrical Connection Unit>

FIG. 1 is a cross-sectional view illustrating an electrical connection unit 1 of an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a main body MU, a metal plate (a support member or a metal member) 80, an insulating sheet 91 (see FIG. 8), a plurality of heat transfer members 92, and an insulating cover 93.

### <2. Main Body>

First, the main body MU will be described.

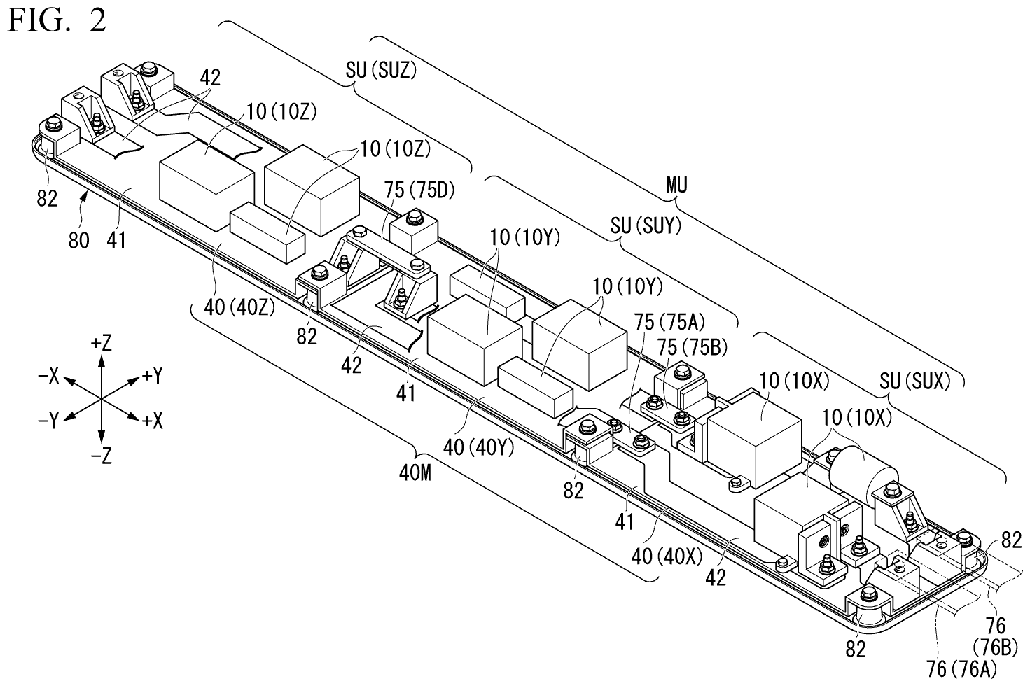

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting a plurality of subunits SU. In the present embodiment, the main body MU includes three subunits SU (subunits SUX, SUY, and SUZ). Each subunit SU may be referred to as a “circuit constitution body”. One of the circuit constitution bodies SUX, SUY, and SUZ is an example of a “first circuit constitution body”. Another one of the circuit constitution bodies SUX, SUY, and SUZ is an example of a “second circuit constitution body”. Each subunit SU is supported by an upper surface 81a (see FIG. 8) of the flat surface portion 81 of the metal plate 80. The upper surface 81a of the flat surface portion 81 is a support surface that supports the three subunits SU via fixing portions 52 and 82 that will be described later.

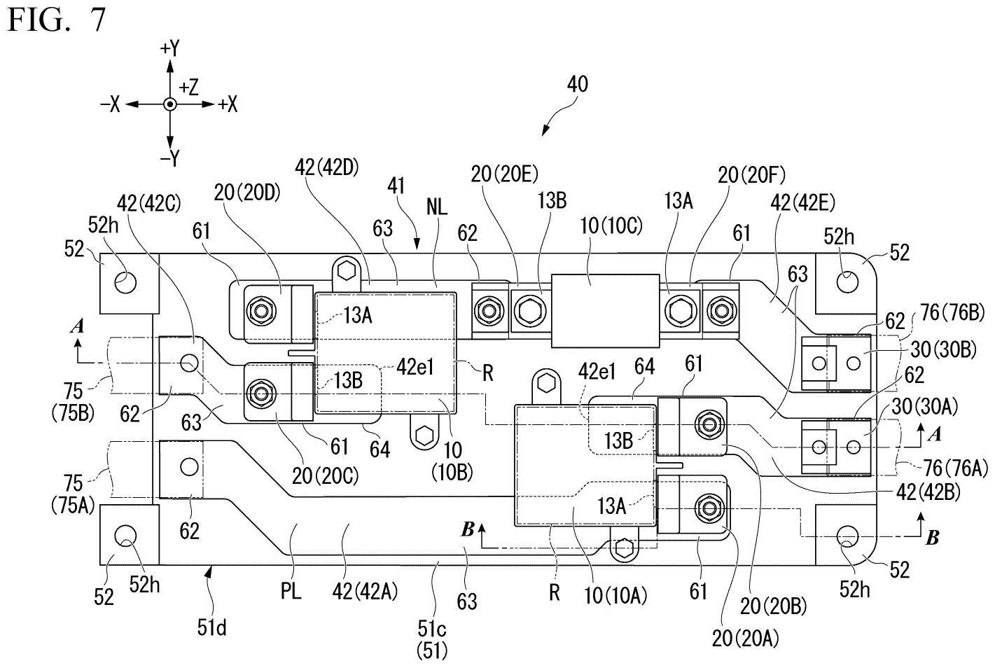

The subunit SUX has an electrical first function. The subunit SUX includes, for example, a plurality of electronic components 10X and a first routing board (mounting member) 40X. The plurality of electronic components 10X are electrically connected to the first routing board 40X. The flat surface portion 51 of the first routing board 40X is disposed (in parallel) along the upper surface 81a of the flat surface portion 81 of the metal plate 80. An upper surface 51c (a surface opposite to the metal plate 80; and see FIG. 8) of the flat surface portion 51 of the first routing board 40X is a component mounting surface on which the plurality of electronic components 10X are mounted. In the present disclosure, “mounting” is not limited to a case where the electronic component 10 is directly fixed, and also includes a case where the electronic component 10 is fixed via another component (for example, the connection component 20). The component mounting surface is an example of a “base surface”. The upper surface 51c (a component mounting surface or a base surface) of the first routing board 40X is formed by, for example, a first surface 51a of a flat surface portion 51 of the base plate 41 that will be described later and an upper surface of the bus bar 42. A circuit component mounting region 51d (see FIG. 7) on which the plurality of electronic components 10X are mounted is formed on the component mounting surface. The circuit component mounting region 51d is a portion facing the plurality of electronic components 10X when viewed from the Z direction. The circuit component mounting region 51d is an example of a “facing region”.

The circuit component mounting region 51d has, for example, a rectangular shape slightly smaller than the rectangular flat surface portion 51 in a plan view viewed from the normal direction (Z direction) of the regions 51c and 81a of the flat surface portions 51 and 81. The circuit component mounting region 51d has a rectangular shape. Fixing portions 52 for fixing the subunit SUX to the metal plate 80 are respectively disposed at four corner portions (top portions) of the rectangular circuit component mounting region 51d. Each fixing portion 52 is disposed to surround the outside of the circuit component mounting region 51d when viewed from the Z direction.

The subunit SUY has an electrical second function. The second function is a function different from the first function. The subunit SUY includes, for example, a plurality of electronic components 10Y and a second routing board (mounting member) 40Y The plurality of electronic components 10Y are electrically connected to the second routing board 40Y The flat surface portion 51 of the second routing board 40Y is disposed (in parallel) along the upper surface 81a of the flat surface portion 81 of the metal plate 80. A region 51c (a surface opposite to the metal plate 80) of the second routing board 40Y is a component mounting surface on which the plurality of electronic components 10Y are mounted. The region 51c (a component mounting surface or a base surface) of the second routing board 40Y is formed by, for example, the first surface 51a of the flat surface portion 51 of the base plate 41 that will be described later and the upper surface of the bus bar 42. A circuit component mounting region 51d on which the plurality of electronic components 10Y are mounted is formed on the component mounting surface. The circuit component mounting region 51d is a portion facing the plurality of electronic components 10Y when viewed from the Z direction. The circuit component mounting region 51d is an example of a “facing region”.

The circuit component mounting region 51d has a rectangular shape slightly smaller than the rectangular flat surface portion 51 in a plan view viewed from the normal direction (Z direction) of the regions 51c and 81a of the flat surface portions 51 and 81. The circuit component mounting region 51d has a rectangular shape. Fixing portions 52 for fixing the subunit SUY to the metal plate 80 are respectively disposed at four corner portions (top portions) of the rectangular circuit component mounting region 51d. Each fixing portion 52 is disposed to surround the outside of the circuit component mounting region 51d when viewed from the Z direction.

The subunit SUZ has an electrical third function. The third function is a function different from the first function and the second function. The subunit SUZ includes, for example, a plurality of electronic components 10Z and a third routing board (mounting member) 40Z. The plurality of electronic components 10Z are electrically connected to the third routing board 40Z. The flat surface portion 51 of the third routing board 40Z is disposed (in parallel) along the upper surface 81a of the flat surface portion 81 of the metal plate 80. A region 51c (a surface opposite to the metal plate 80) of the third routing board 40Z is a component mounting surface on which the plurality of electronic components 10Z are mounted. The region 51c (a component mounting surface or a base surface) of the third routing board 40Z is formed by, for example, the first surface 51a of the flat surface portion 51 of the base plate 41 that will be described later and the upper surface of the bus bar 42. A circuit component mounting region 51d on which the plurality of electronic components 10Z are mounted is formed on the component mounting surface. The circuit component mounting region 51d is a portion facing the plurality of electronic components 10Z when viewed from the Z direction. The circuit component mounting region 51d is an example of a “facing region”.

The circuit component mounting region 51d has a rectangular shape slightly smaller than the rectangular flat surface portion 51 in a plan view viewed from the normal direction of the regions 51c and 81a of the flat surface portions 51 and 81. The circuit component mounting region 51d has a rectangular shape. Fixing portions 52 for fixing the subunit SUZ to the metal plate 80 are respectively disposed at four corner portions (top portions) of the rectangular circuit component mounting region 51d. Each fixing portion 52 is disposed to surround the outside of the circuit component mounting region 51d when viewed from the normal direction of the regions 51c and 81a of the flat surface portions 51 and 81.

In the present embodiment, the three subunits SUX, SUY, and SUZ are disposed to be arranged in the X direction. For example, the subunit SUX is disposed on the +X direction side with respect to the subunit SUY. The subunit SUX and the subunit SUY are electrically connected via a plurality of coupling bus bars 75 extending between the first routing board 40X and the second routing board 40Y. On the other hand, the subunit SUZ is disposed on the −X direction side with respect to the subunit SUY The subunit SUZ and the subunit SUY are electrically connected via a plurality of coupling bus bars 75 extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. As a result, one large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the subunit SUX, the subunit SUY, and the subunit SUZ are not distinguished, the subunits are simply referred to as “subunit SU”. In addition, in a case where the electronic component 10X, the electronic component 10Y, and the electronic component 10Z are not distinguished, the electronic components are simply referred to as “electronic component 10”. In a case where the first routing board 40X, the second routing board 40Y, and the third routing board 40Z are not distinguished, the routing boards are simply referred to as “routing board 40”.

Note that the main body MU need not be divided into a plurality of subunits SU instead of the example described above. That is, the main body MU may be formed by the plurality of electronic components 10 and one routing board 40. In addition, the two or more subunits SU are not limited to the subunits SU having different functions, and may be the subunits SU having the same function.

In the present embodiment, for example, a plurality of subunits (circuit constitution bodies) SU having different heat generation timings will be exemplified. For example, during traveling (discharging) of a vehicle on which the electrical connection unit 1 is mounted, the circuit constitution bodies SUX and SUY generate heat. On the other hand, during charging of the vehicle, the circuit constitution body SUZ generates heat.

A synthetic resin portion (routing board 40) that expands due to heat generated by the circuit constitution bodies SUX and SUY during traveling of the vehicle is fixed to the metal plate 80 around the circuit constitution bodies SUX and SUY. Therefore, expansion/warpage of the synthetic resin portion of the circuit constitution bodies SUX and SUY is curbed from acting as thermal stress on the synthetic resin portion of the circuit constitution body SUZ.

On the other hand, a synthetic resin portion (routing board 40) that expands due to heat generated by the circuit constitution body SUZ during vehicle charging is fixed to the metal plate 80 around the circuit board SUZ. Therefore, expansion/warpage of the circuit constitution body SUZ is curbed from acting as thermal stress on the synthetic resin portions of the circuit constitution bodies SUX and SUY

As a result, the number of times of thermal stress acting on the synthetic resin portion of each circuit constitution body SU can be reduced, and the life of each synthetic resin portion can be lengthened.

The plurality of circuit constitution bodies 40 having different heat generation timings may be circuit constitution bodies for switching charging voltages (400 V/800 V).

### <3. Constitution of Subunit>

Next, a constitution of the subunit SU will be described.

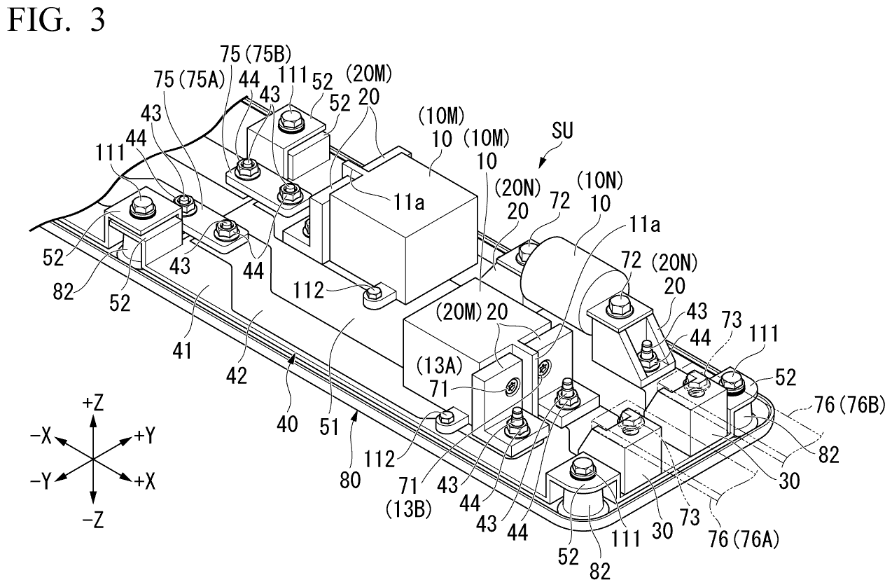

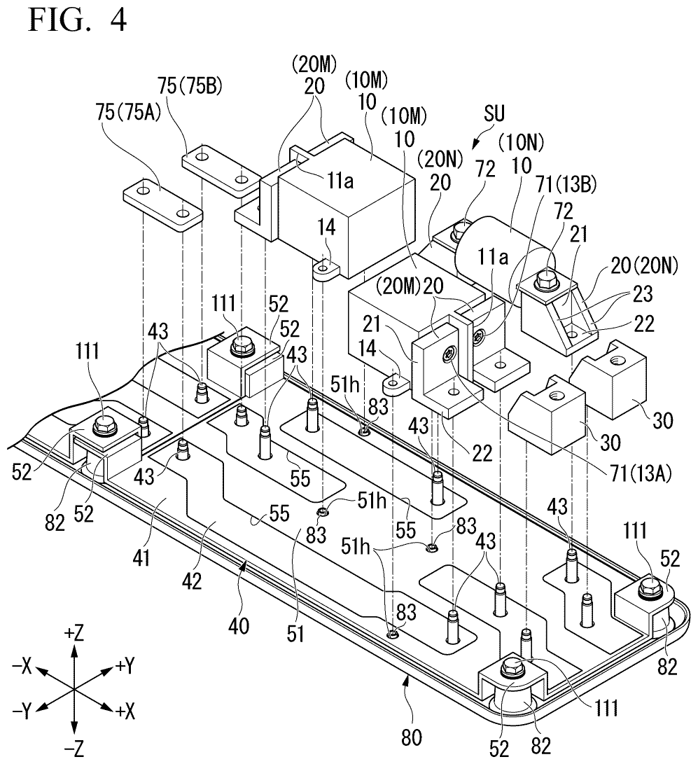

FIG. 3 is a perspective view for describing the subunit SU. FIG. 4 is a partially exploded perspective view of the subunit SU. The subunit SU includes, for example, a plurality of electronic components 10, a plurality of connection components 20 for component connection, a plurality of connection components 30 for external connection, and a routing board 40. The connection components 20 and 30 are members forming an energization path in the vertical direction. The connection components 20 and 30 may be referred to as “vertical routing members”.

### <3.1 Electronic Component and Connection Component for Component Connection>

First, the electronic component 10 and the connection component 20 for component connection will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization. Hereinafter, a first-type electronic component 10M and a second-type electronic component 10N will be described as examples of the electronic component 10.

The connection component 20 is a component that electrically connects the electronic component 10 to the routing board 40. The connection component 20 forms part of an energization path in the subunit SU. The connection component 20 is made of a metal (for example, copper or a copper alloy). The connection component 20 may be referred to as a “metal component”. Hereinafter, a first-type connection component 20M and a second-type connection component 20N will be described as examples of the connection component 20.

### <3.1.1 First-Type Electronic Component>

The first-type electronic component 10M is an electronic component in which a plurality of terminals 13 are disposed to be arranged at one end of the electronic component 10M. The electronic component 10M includes, for example, a component body 12 having a rectangular parallelepiped shape, a plurality of terminals 13, and a plurality of attachment portions 14.

### (Component Body)

The component body 12 is a portion that performs a main function of the electronic component 10M. For example, in a case where the electronic component 10M is a relay, the component body 12 includes a switch (for example, a contact) that switches between a conductive state and a non-conductive state. For example, in a case where the electronic component 10M is a fuse, the component body 12 includes a fusion portion that is fused when an overcurrent flows. For example, in a case where the electronic component 10M is a capacitor, the component body 12 includes a portion that stores electric charge.

The component body 12 accommodates a constitution component in an outer member (case) that forms most of the outer shape of the electronic component 10M. The case is made of, for example, a synthetic resin and has an insulating property. The component body 12 includes an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the component body 12 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, part of the insulating rib 11a is disposed between first portions 21 (that will be described later) of two connection components 20M connected to the electronic component 10M. The insulating rib 11a electrically insulates the first portions 21 of the two connection components 20M connected to the electronic component 10M from each other.

### (Terminal)

The terminal 13 is an electrical connection portion exposed to the outside of the component body 12. The terminal 13 is electrically connected to the constitution components in the case. In the present embodiment, the electronic component 10M includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side.

In the present embodiment, the terminal 13A and the terminal 13B are provided at one end of the electronic component 10M in the horizontal direction (for example, the X direction). The terminal 13A and the terminal 13B are disposed to be arranged in the horizontal direction (for example, the Y direction). Each terminal 13 has an attachment hole (not illustrated) to which a fastening member 71 (for example, a screw or a bolt) that will be described later is attached. The attachment hole of each terminal 13 is open in the horizontal direction (for example, the X direction). An inner circumferential surface of the attachment hole of each terminal 13 has a screw groove.

### (Attachment Portion)

The attachment portion 14 is a portion for fixing the electronic component 10M. The attachment portion 14 has an attachment hole (without a number) to which a fastening member 112 (for example, a screw or a bolt; and see FIG. 8) that will be described later is attached. The attachment hole is open in the Z direction. The attachment hole is an insertion hole through which the fastening member 112 passes. A fixing destination of the attachment portion 14 will be described later.

### <3.1.2 First-Type Connection Component>

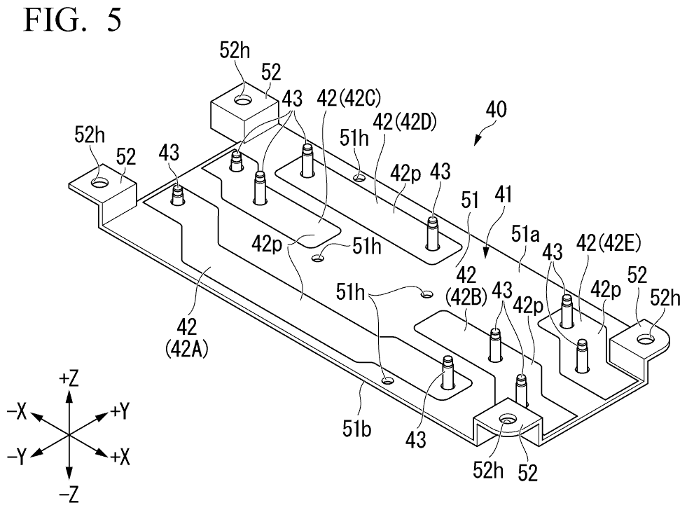

The first-type connection component 20M is a component that electrically connects the first-type electronic component 10M to the routing board 40. In the present embodiment, the connection component 20M electrically connects the electronic component 10M to the bus bar 42 (see FIG. 5) included in the routing board 40. The connection component 20M includes, for example, a first portion 21 rising above the routing board 40 and a second portion 22 disposed along the routing board 40.

### (First Portion)

The first portion 21 of the connection component 20M is a portion connected to the terminal 13 of the electronic component 10M. The first portion 21 is a plate-shaped or rectangular parallelepiped portion extending in the Z direction. The first portion 21 extends in the Z direction along one end (for example, an end in the X direction) of the electronic component 10M. The first portion 21 is a standing portion that stands in the Z direction with respect to the routing board 40 (for example, with respect to a bus bar 42 that will be described later). The first portion 21 is adjacent to the electronic component 10M in the horizontal direction (for example, the X direction). For example, the first portion 21 is adjacent to the terminal 13 of the electronic component 10M in the horizontal direction (for example, the X direction), and is connected to the terminal 13 of the electronic component 10M from the horizontal direction (for example, the X direction). The first portion 21 of the connection component 20M is physically and electrically connected to the terminal 13 of the electronic component 10M by inserting the fastening member 71 (for example, a screw or a bolt) into an attachment hole (not illustrated) and screwing and fastening the fastening member into the attachment hole of the terminal 13 of the electronic component 10M.

### (Second Portion)

The second portion 22 of the connection component 20M is a portion connected to the bus bar 42 (see FIG. 5). The second portion 22 protrudes in the horizontal direction (for example, the X direction) from end of the first portion 21 on the −Z direction side. The second portion 22 is a plate portion provided in the horizontal direction. The second portion 22 is adjacent (overlaps) to the bus bar 42 in the Z direction, and is connected to the bus bar 42 from the Z direction. The second portion 22 penetrates the fastening member 43 (for example, a screw or a bolt; and see FIG. 5) protruding from the bus bar 42 in the +Z direction. An engagement member 44 (for example, a nut; and see FIG. 3) is screwed and fastened to the fastening member 43 that has penetrated the second portion 22, and thus the bus bar 42 is physically and electrically connected.

In the present embodiment, the first portion 21 and the second portion 22 form one L-shaped connection component 20M.

### <3.1.3 Second-Type Electronic Component>

The second-type electronic component 10N is an electronic component in which two terminals 13 are separately disposed at both ends in the horizontal direction of the electronic component 10N. The electronic component 10N includes, for example, a component body 12 and a plurality of terminals 13. Note that, among the constitutions of the electronic component 10N, constitutions having functions similar to those of the electronic component 10M are denoted by the same reference numbers. In this case, in the description regarding the electronic component 10N, the “electronic component 10M” may be replaced with the “electronic component 10N” in the description regarding the electronic component 10M described above.

In the electronic component 10N, the terminal 13A and the terminal 13B are disposed separately at both ends in the horizontal direction (for example, the X direction) of the electronic component 10N. Each terminal 13 has an attachment hole (not illustrated) to which a fastening member 72 (for example, a screw or a bolt) that will be described later is attached. The attachment hole of each terminal 13 is open in the Z direction. For example, the attachment hole of each terminal 13 is an insertion hole through which the fastening member 72 passes.

### <3.1.4 Second-Type Connection Component>

The second-type connection component 20N is a component that electrically connects the second-type electronic component 10N and the routing board 40. In the present embodiment, the connection component 20N electrically connects the electronic component 10N to the bus bar 42 (see FIG. 5) included in the routing board 40. The connection component 20N includes, for example, a first portion 21, a second portion 22, and a third portion 23.

### (First Portion)

The first portion 21 of the connection component 20N is a portion connected to the terminal 13 of the electronic component 10N. The first portion 21 is a rectangular parallelepiped portion extending in the Z direction. The first portion 21 is a standing portion that stands in the Z direction with respect to the routing board 40 (for example, with respect to the bus bar 42). The first portion 21 is adjacent (overlaps) to the terminal 13 of the electronic component 10N in the Z direction, and is connected to the terminal 13 of the electronic component 10N from the Z direction. The first portion 21 of the connection component 20N has an attachment hole (not illustrated) to which the fastening member 72 (for example, a screw or a bolt) that will be described later is attached. The attachment hole of the connection component 20N is open upward and has a screw groove on the inner circumferential surface. The terminal 13 of the electronic component 10N is physically and electrically connected to the terminal 13 of the electronic component 10N by penetrating the fastening member 72 and screwing and fastening the fastening member into the attachment hole of the connection component 20N.

### (Second Portion)

The second portion 22 of the connection component 20N is a portion connected to the bus bar 42 (see FIG. 5). The second portion 22 protrudes in the horizontal direction (for example, the X direction) from end of the first portion 21 on the −Z direction side. The second portion 22 is a plate portion provided in the horizontal direction. The second portion 22 is adjacent (overlaps) to the bus bar 42 in the Z direction, and is connected to the bus bar 42 from the Z direction. The second portion 22 is physically and electrically connected to the bus bar 42 by passing through the fastening member 43 (for example, a screw or a bolt; and see FIG. 5) protruding from the bus bar 42 in the +Z direction and screwing and fastening the engagement member 44 (for example, a nut; and see FIG. 3) into the fastening member 43.

### (Third Portion)

The third portion 23 is a standing wall (side wall) standing in the +Z direction from both ends of the second portion 22 in the horizontal direction. The third portion 23 is a wall provided in the Z direction. The third portion 23 is connected to the first portion 21 and is also connected to the second portion 22. For example, the third portion 23 extends obliquely so as to increase in the X direction as proceeding in the −Z direction. The third portion 23 may be provided in the connection component 20M described above. On the other hand, the connection component 20N need not have the third portion 23.

### <3.2 Connection Component for External Connection>

Next, the connection component 30 for external connection will be described.

The connection component 30 is a component that electrically connects the external connection bus bar 76 to the routing board 40. In the present embodiment, the connection component 30 electrically connects the external connection bus bar 76 to the bus bar 42 (see FIG. 5) included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples. The connection component 30 has, for example, a first portion, a second portion, and a third portion similar to those of the connection component 20M, and a detailed description thereof will be omitted.

The external connection bus bar 76 is physically and electrically connected to the upper end (the upper end of the first portion) of the connection component 30 via the fastening member 73 (for example, a screw or a bolt).

A lower portion (second portion) of the connection component 30 is physically and electrically connected to the bus bar 42 by passing through the fastening member 43 (for example, a screw or a bolt; and see FIG. 5) protruding from the bus bar 42 in the +Z direction and screwing and fastening an engagement member 44 (for example, a nut; and see FIG. 3) into the fastening member 43.

### <3.3 Routing Board>

Next, the routing board 40 will be described.

FIG. 5 is a perspective view illustrating the routing board 40. The routing board 40 is a member that forms at least part of an energization path between the plurality of electronic components 10 and/or at least part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding. For example, an opening (corresponding to an accommodation portion 55 that will be described later) capable of fixing the bus bar 42 through fitting or the like may be formed in the routing board 40 formed separately from the bus bar 42, and the bus bar 42 may be fixed to the opening to form a bus bar insert plate.

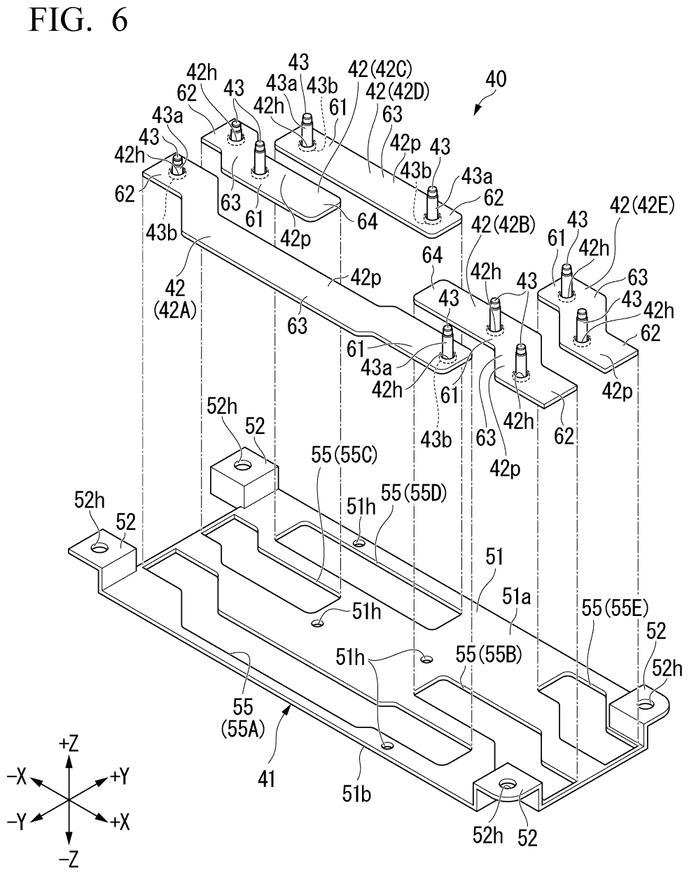

FIG. 6 is a partially exploded perspective view of the routing board 40. Hereinafter, for convenience of description, the base plate 41, the bus bar 42, and the fastening member 43 will be described with reference to the drawings in which the routing board 40 is partially exploded.

### (Base Plate)

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 is an example of each of a “base member” and a “mounting member”. The base plate 41 may be referred to as an “insulating substrate”. The base plate 41 includes, for example, a flat surface portion 51 and a plurality of fixing portions 52. The fixing portion 52 will be described later.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 forms a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41.

The flat surface portion 51 has a first surface 51a and a second surface 51b. The first surface 51a is a surface directed in the +Z direction. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed in the −Z direction. The second surface 51b is a flat surface provided in the horizontal direction. The second surface 51b faces the metal plate 80 (see FIG. 1). The thickness direction (a plate thickness direction or a normal direction of the first surface 51a and the second surface 51b) of the flat surface portion 51 is the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41).

Each accommodation portion 55 has an outer shape corresponding to the shape of the bus bar 42 to be accommodated when viewed from the Z direction. In the present embodiment, the flat surface portion 51 includes, for example, five accommodation portions 55A, 55B, 55C, 55D, and 55E as the plurality of accommodation portions 55. The accommodation portion 55A is provided to correspond to a bus bar 42A that will be described later, and accommodates the bus bar 42A. The accommodation portion 55B is provided to correspond to a bus bar 42B that will be described later, and accommodates the bus bar 42B. The accommodation portion 55C is provided to correspond to a bus bar 42C that will be described later, and accommodates the bus bar 42C. The accommodation portion 55D is provided to correspond to a bus bar 42D that will be described later, and accommodates the bus bar 42D. The accommodation portion 55E is provided to correspond to a bus bar 42E that will be described later, and accommodates the bus bar 42E.

### (Bus Bar)

The bus bar 42 is a routing member (electrical connection member) included in the routing board 40. The bus bar 42 is, for example, a routing member for electrically connecting the plurality of electronic components 10. Alternatively, the bus bar 42 may be a routing member for connecting the electronic component 10 to an external device. The bus bar 42 is made of a metal (for example, copper or a copper alloy) and has conductivity. In the present embodiment, the routing board 40 includes, for example, five bus bars 42A, 42B, 42C, 42D, and 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E include portions arranged on the same plane. The five bus bars 42A, 42B, 42C, 42D, and 42E are held by the flat surface portion 51 of the base plate 41.

At least part of each bus bar 42 has a plate shape formed in the horizontal direction. At least part of each bus bar 42 is accommodated in the accommodation portion 55 and extends along the flat surface portion 51. That is, at least part of each bus bar 42 extends along the first surface 51a of the flat surface portion 51. At least part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51. The upper and lower surfaces of each bus bar 42 may be flush with the upper and lower surfaces (the first surface 51a and the second surface 51b) of the flat surface portion 51. The upper surface of each bus bar 42 and the upper surface (first surface 51a) of the flat surface portion 51 form a component mounting surface of the routing board 40. Hereinafter, a portion of each bus bar 42 that is accommodated in the accommodation portion 55 and extends along the flat surface portion 51 may be referred to as a “plate portion 42p”. The bus bar 42 is a member that forms a horizontal energization path. The bus bar 42 may be referred to as a “horizontal routing member”.

FIG. 7 is a plan view illustrating the routing board 40. The plate portion 42p of each bus bar 42 has, for example, a first connection portion 61, a second connection portion 62, and an extending portion 63.

The first connection portion 61 is a portion in contact with one connection component 20 (hereinafter referred to as a “first connection component 20”). The first connection component 20 is a connection component that connects one electronic component 10 (hereinafter referred to as a “first electronic component 10”) to the bus bar 42. The first connection portion 61 is a portion of the bus bar 42 overlapping the first connection component 20 when viewed from the Z direction. The first connection portion 61 is adjacent to the first connection component 20 in the Z direction, and is connected to the first connection component 20 from the Z direction.

The second connection portion 62 is a portion in contact with another connection component 20 (hereinafter referred to as a “second connection component 20”). The second connection component 20 is a connection component that connects another electronic component 10 (hereinafter referred to as a “second electronic component 10”) included in the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction, and is connected to the second connection component 20 from the Z direction.

Note that the second connection portion 62 may be a portion in contact with another connection component 30 (hereinafter referred to as a “second connection component 30”) instead of the above example. The connection component 30 is a connection component for connecting an external device to the bus bar 42. In this case, the second connection portion 62 is a portion of the bus bar 42 overlapping the second connection component 30 when viewed from the Z direction. The second connection portion 62 is adjacent to the second connection component 30 in the Z direction, and is connected to the second connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction, and is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 is accommodated in the accommodation portion 55 at least over the first connection portion 61 and the second connection portion 62 and extends along the flat surface portion 51. For example, the first connection portion 61, the second connection portion 62, and the extending portion 63 are accommodated in the accommodation portion 55 and extend along the flat surface portion 51.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 has a portion extending linearly in the X direction. This portion extends over the region R overlapping the electronic component 10 when viewed from the Z direction, over the +X direction side and the −X direction side of the region R. That is, the bus bar 42 is accommodated in the accommodation portion 55 to be easily routed through a better path (for example, a path with a shorter distance) without being disturbed by the presence of the electronic component 10.

The one or more bus bars 42 may have an extension 64 in addition to the first connection portion 61, the second connection portion 62, and the extending portion 63. The extension 64 is a portion where the bus bar 42 extends or branches for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 is accommodated in the accommodation portion 55 and extends along the flat surface portion 51. The extension 64 extends to the region R overlapping the electronic component 10 when viewed from the Z direction, and has an end 42e1 of the bus bar 42 at a position overlapping the electronic component 10 when viewed from the Z direction.

### <4. Metal Plate, Insulating Sheet, Heat Transfer Member, and Insulating Cover>

Next, the metal plate 80, the insulating sheet 91, the heat transfer member 92, and the insulating cover 93 will be described.

### <4.1 Metal Plate>

FIG. 8 is a partially exploded perspective view of the electrical connection unit 1. The metal plate 80 is a member for securing rigidity of the electrical connection unit 1 and enhancing a heat dissipation property of the electrical connection unit 1. The metal plate 80 is made of a metal (for example, aluminum or an aluminum alloy). The metal plate 80 may be referred to as a “rigid member”. The metal plate 80 is a single metal plate.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. The metal plate 80 includes, for example, a flat surface portion 81, a plurality of fixing portions 82, and a plurality of fixing portions 83.

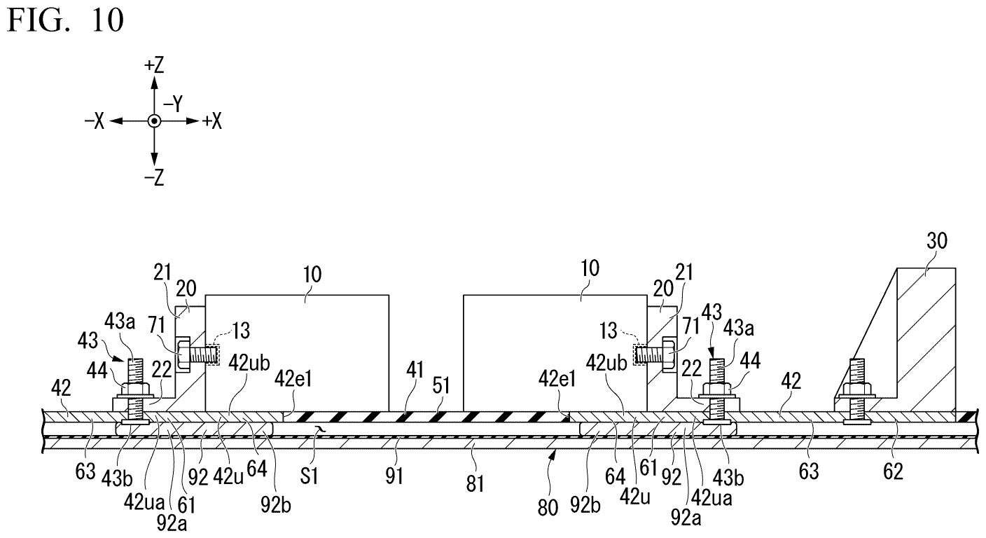

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the three subunits SU from below. The flat surface portion 81 faces the routing boards 40 of the three subunits SU. In the present embodiment, the metal plate 80 has a gap S1 (see FIG. 10) between the metal plate and the second surface 51b of the flat surface portion 51 of each subunit SU, and faces the second surface 51b of the flat surface portion 51 of each subunit SU.

The fixing portion 82 is a fixing portion for fixing the base plate 41 of each subunit SU to the metal plate 80. The fixing portion 82 is provided at a position corresponding to the fixing portion 52 of the base plate 41 of each subunit SU when viewed from the Z direction. The fixing portion 82 is a cylindrical or prismatic boss protruding in the +Z direction from the flat surface portion 81 of the metal plate 80. The fixing portion 82 will be described in detail later.

The fixing portion 83 is a fixing portion for directly fixing the electronic component 10 of each subunit SU to the metal plate 80 without interposing the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The fixing portion 83 will be described in detail later.

### <4.2 Insulating Sheet>

The insulating sheet 91 is an insulating member for electrically insulating the metal plate 80 and the bus bars 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between the flat surface portion 81 of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding the fixing portion 82 and the fixing portion 83 of the metal plate 80. Note that, instead of the above example, the insulating sheet 91 may be provided between the routing board 40 of each subunit SU and the plurality of heat transfer members 92. Note that, in a case where the heat transfer member 92 has an insulating property and the necessary insulating property is secured by the heat transfer member 92, the insulating sheet 91 may be omitted.

### <4.3 Heat Transfer Member>

The heat transfer member 92 is a member for transferring heat generated by the electronic component 10 at the time of energization and/or heat (Joule heat) generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

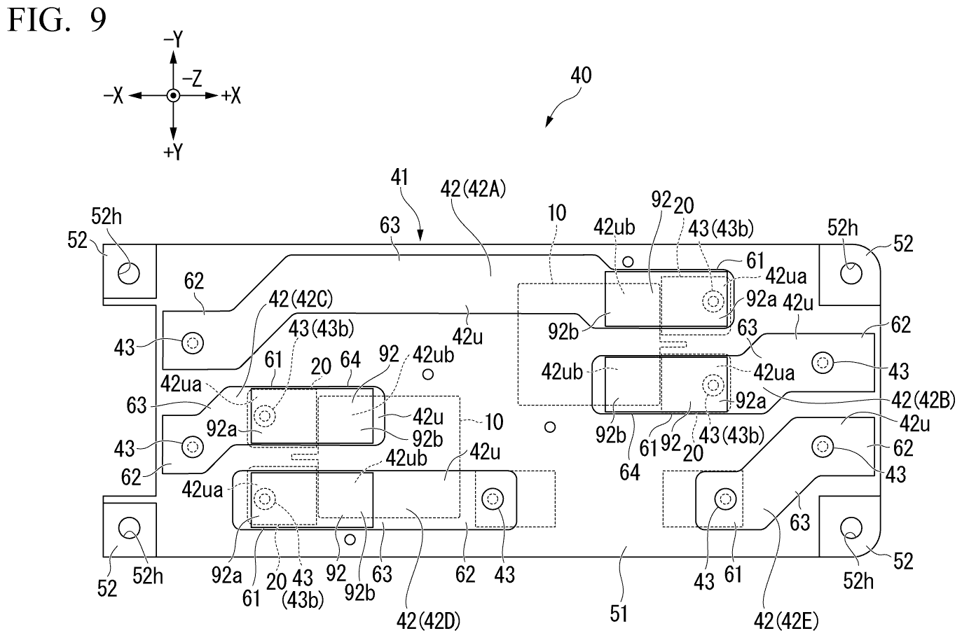

FIG. 9 is a bottom view illustrating the routing board 40. In the present embodiment, the plurality of heat transfer members 92 are partially provided in the routing board 40. For example, the plurality of heat transfer members 92 are disposed at positions overlapping part of the bus bar 42 when viewed from the Z direction. More specifically, the plurality of heat transfer members 92 are disposed at positions overlapping part of the bus bar 42 in the vicinity of the electronic component 10 (for example, the electronic components 10A and 10B) when viewed from the Z direction. In the present embodiment, the plurality of heat transfer members 92 are disposed at positions overlapping the connection component 20 when viewed from the Z direction.

FIG. 10 is a cross-sectional view taken along line A-A of the structure illustrated in FIG. 7. In the present embodiment, the heat transfer member 92 is disposed between the metal plate 80 and the bus bar 42. The heat transfer member 92 transfers heat transferred from the electronic component 10 to the bus bar 42 and/or heat generated by the bus bar 42 from the bus bar 42 to the metal plate 80.

In the present embodiment, part of the heat transfer member 92 is in contact with the bus bar 42 at a position overlapping the connection component 20 when viewed from the Z direction. In this case, the heat transfer member 92 easily transfers the heat transferred from the terminal 13 of the electronic component 10 to the connection component 20 from the connection component 20 to the metal plate 80 via the bus bar 42.

In the present embodiment, part of the heat transfer member 92 is disposed at a position overlapping the head 43b of the fastening member 43 when viewed from the Z direction, and is in contact with the head 43b of the fastening member 43. In this case, the heat transfer member 92 easily transfers the heat transferred from the terminal 13 of the electronic component 10 to the connection component 20 from the fastening member 43 to the metal plate 80.

In the present embodiment, part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 10, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64.

### <4.4 Insulating Cover>

Referring to FIG. 1 again, the insulating cover 93 will be described. The insulating cover 93 is a member for preventing the main body MU from touching the energization path. The insulating cover 93 is made of, for example, a synthetic resin and has an insulating property. The insulating cover 93 has, for example, a box shape that is open on the −Z direction side. The insulating cover 93 has a plurality of vent holes 93h. The insulating cover 93 is attached to the metal plate 80 in the Z direction. Note that the insulating cover 93 is not limited to a box-shaped member, and may be a sheet-shaped member that covers the energization path of the main body MU.

### <7. Fixing Structure>

Next, a fixing structure of the subunit SU will be described.

### <7.1 Structure of Metal Plate>

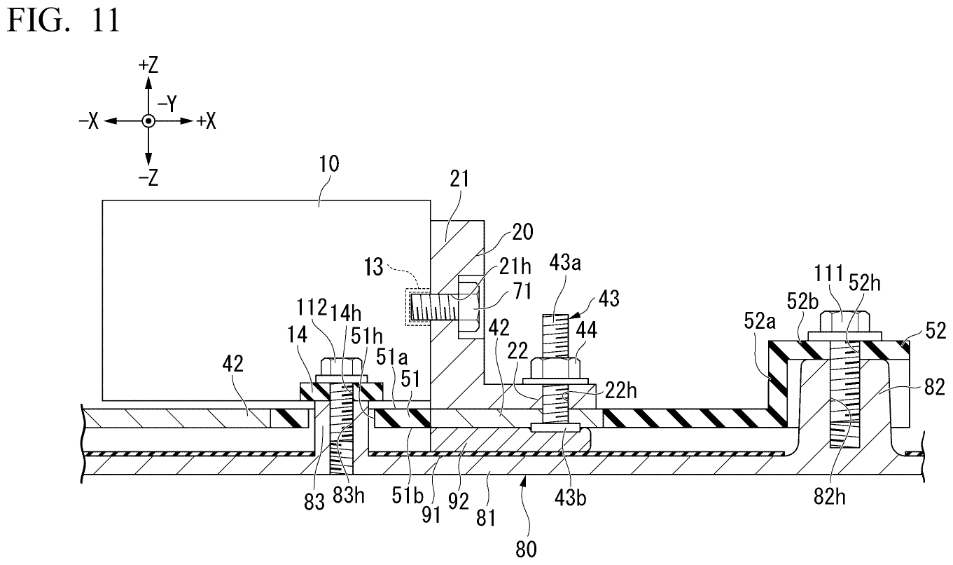

FIG. 11 is a cross-sectional view taken along line B-B of the structure illustrated in FIG. 7. As described above, the metal plate 80 includes the fixing portion 82 and the fixing portion 83.

The fixing portion 82 is a boss protruding in the +Z direction from the flat surface portion 81 of the metal plate 80. For example, the fixing portion 82 protrudes to the +Z direction side from the first surface 51a of the flat surface portion 51 of the base plate 41. In the present embodiment, the fixing portion 82 protrudes more in the +Z direction than the fixing portion 83 that will be described later. The fixing portion 82 faces the fixing portion 52 of the base plate 41 in the Z direction. The fixing portion 82 has an engagement hole 82h that is open in the +Z direction. An inner circumferential surface of the engagement hole 82h has a screw groove.

The fixing portion 83 is a boss protruding in the +Z direction from the flat surface portion 81. The fixing portion 83 is inserted into a through-hole 51h (that will be described later) of the flat surface portion 51 of the base plate 41. For example, the fixing portion 83 passes through the through-hole 51h of the flat surface portion 51 and protrudes to the same position as the first surface 51a of the flat surface portion 51 or protrudes beyond a position of the first surface 51a of the flat surface portion 51 (a position on the +Z direction side with respect to the first surface 51a). The fixing portion 83 faces the attachment portion 14 of the electronic component 10 in the Z direction. The fixing portion 83 has an engagement hole 83h that is open in the +Z direction. An inner circumferential surface of the engagement hole 83h has a screw groove.

The fastening member 112 (for example, a screw or a bolt) passes through the attachment portion 14 of the electronic component 10 from the +Z direction side. When the fastening member 112 passed through the attachment portion 14 of the electronic component 10 is engaged with the engagement hole 83h of the fixing portion 83 of the metal plate 80, the electronic component 10 is fixed to the metal plate 80 without passing through the base plate 41.

### <7.2 Structure of Routing Board>

The base plate 41 has the fixing portion 52 fixed to the fixing portion 82 of the metal plate 80. The fixing portion 52 includes, for example, a standing plate portion 52a and a horizontal plate portion (upper plate portion) 52b.

The standing plate portion 52a stands in the +Z direction from the end of the flat surface portion 51 of the base plate 41. The standing plate portion 52a is a plate portion provided in the Y direction and the Z direction. The thickness direction of the standing plate portion 52a is the X direction.

The horizontal plate portion 52b extends in the horizontal direction from the end of the standing plate portion 52a in the +Z direction. The horizontal plate portion 52b is a plate portion provided in the horizontal direction. The horizontal plate portion 52b faces the fixing portion 82 of the metal plate 80 in the Z direction. The horizontal plate portion 52b has an insertion hole 52h facing the engagement hole 82h of the fixing portion 82 of the metal plate 80. A fastening member 111 (for example, a screw or a bolt) passes through the insertion hole 52h. When the fastening member 111 that has passed through the insertion hole 52h of the fixing portion 52 of the base plate 41 is engaged with the engagement hole 82h of the fixing portion 82 of the metal plate 80, the base plate 41 is fixed to the metal plate 80. The horizontal plate portions 52b of the fixing portions 52 of the pair of adjacent subunits SU on the metal plate 80 overlap the upper surface of the boss of the metal plate 80, and are fastened and fixed together via the fastening member 111. The fixing structure including the fixing portions 52 and 82 is shared for fixing the pair of adjacent subunits SU on the metal plate 80.

The flat surface portion 51 of the base plate 41 has the above-described through-hole 51h. The through-hole 51h penetrates the flat surface portion 51 in the Z direction. The through-hole 51h is provided at a position corresponding to the fixing portion 83 of the metal plate 80 when viewed from the Z direction. The fixing portion 83 of the metal plate 80 passes through the through-hole 51h of the base plate 41 and protrudes to the same position as the first surface 51a of the flat surface portion 51 or to the +Z direction side with respect to the first surface 51a of the flat surface portion 51. The attachment portion 14 of the electronic component 10 is fixed to the fixing portion 83 at the same position as the first surface 51a of the flat surface portion 51 or at a position on the +Z direction side with respect to the first surface 51a of the flat surface portion 51.

### <8. Heat Dissipation Path Related to Fixing Structure>

Next, a heat dissipation path related to the fixing portion 83 of the metal plate 80 will be described.

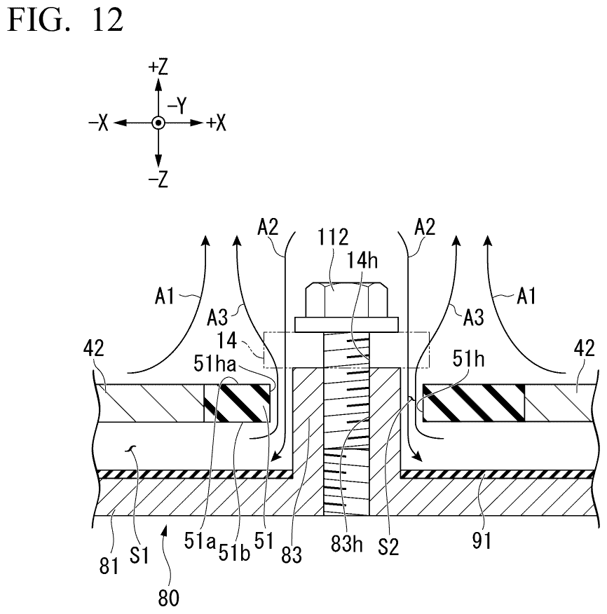

FIG. 12 is a cross-sectional view for describing a heat dissipation path related to the fixing portion 83 of the metal plate 80. In the present embodiment, the fixing portion 83 of the metal plate 80 is not in contact with a high-temperature portion (for example, the terminal 13) of the electronic component 10. In the present embodiment, a gap S2 through which air can pass is provided between the inner circumferential surface 51ha of the through-hole 51h of the base plate 41 and the fixing portion 83. For example, when viewed from the Z direction, the through-hole 51h may be largely open such that part of the through-hole 51h does not overlap the attachment portion 14 of the electronic component 10.

In the present embodiment, the temperature of the fixing portion 83 of the metal plate 80 tends to be lower than the temperature of the bus bar 42. In this case, convection occurs due to a temperature difference between the fixing portion 83 (low temperature) of the metal plate 80 and the bus bar 42 (high temperature).

Specifically, in response to generation of an upward flow of warm air (see an arrow A1) around the bus bar 42, a downward flow (see an arrow A2) passing through the through-hole 51h of the base plate 41 and directed downward from the base plate 41 is generated around the fixing portion 83 of the metal plate 80. When the downward flow is generated, an upward flow (see an arrow A3) that moves the air (warm air) in gap S1 between the metal plate 80 and the base plate 41 upward from base plate 41 is generated near the inner circumferential surface 51ha of the through-hole 51h to be pushed out by the air moving in the downward flow. As a result, the warm air is prevented from being confined in the gap S1 between the metal plate 80 and the base plate 41, and the heat dissipation of the electrical connection unit 1 is promoted.

### Modification Example

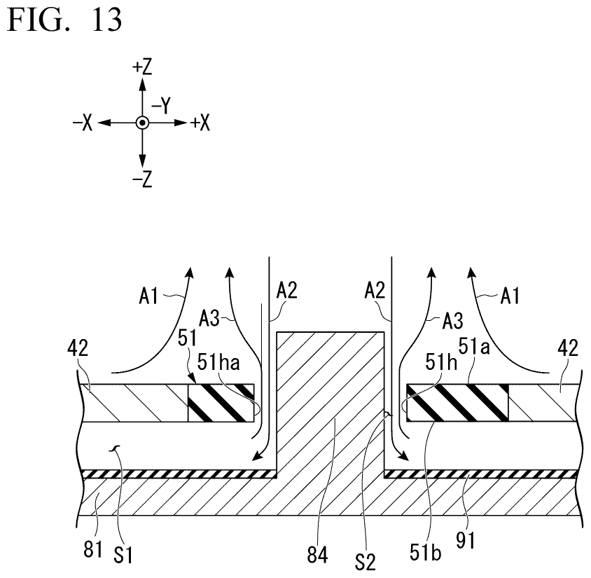

FIG. 13 is a cross-sectional view for describing a modification example of a heat dissipation path. In the present modification example, the metal plate 80 has a protruding portion 84 instead of/in addition to the fixing portion 83. The protruding portion 84 is a protruding portion for heat dissipation. The protruding portion 84 need not be used for the fixing structure. The protruding portion 84 is a cylindrical or prismatic boss protruding in the +Z direction from the flat surface portion 81 of the metal plate 80. The protruding portion 84 is inserted into the through-hole 51h of the flat surface portion 51 of the base plate 41. For example, the protruding portion 84 passes through the through-hole 51h of the flat surface portion 51 and protrudes to the same position as the first surface 51a of the flat surface portion 51 or protrudes beyond a position of the first surface 51a of the flat surface portion 51 (a position on the +Z direction side with respect to the first surface 51a).

According to the constitution of the present modification example, the temperature of the protruding portion 84 of the metal plate 80 tends to be lower than the temperature of the bus bar 42. In this case, convection occurs due to a temperature difference between the protruding portion 84 (low temperature) of the metal plate 80 and the bus bar 42 (high temperature). As a result, air flows indicated by the arrows A1 to A3 described above are generated, and heat dissipation of the electrical connection unit 1 is promoted.

### <9. Absorption Structure for Thermal Expansion/Contraction Related to Fixing Structure>

Next, an absorption structure for thermal expansion/contraction related to the fixing structure will be described.

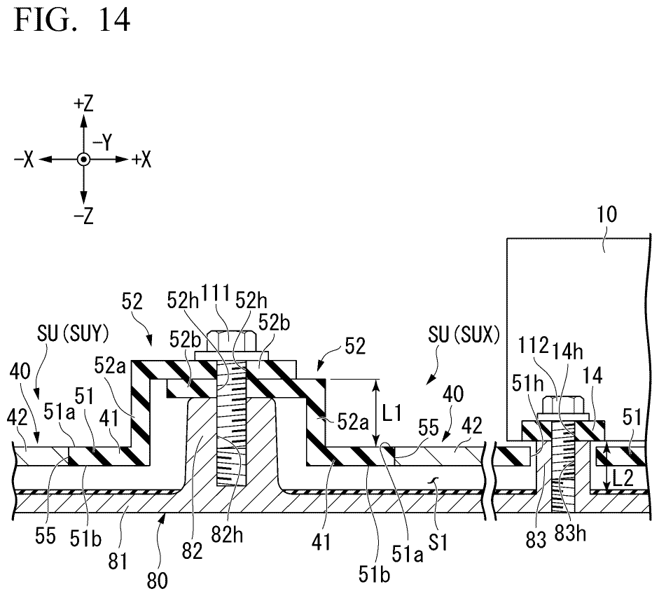

FIG. 14 is a cross-sectional view for describing an absorption structure for thermal expansion/contraction related to the fixing portion 82. In the present embodiment, the routing board 40 of the subunit SUX includes the base plate 41 and the bus bar 42. The flat surface portion 51 of the base plate 41 has the accommodation portion 55 that accommodates the bus bars 42. The fixing portion 52 of the base plate 41 includes a standing plate portion 52a standing in the Z direction from the flat surface portion 51, and a horizontal plate portion 52b extending in the horizontal direction from the +Z direction end of the standing plate portion 52a. The horizontal plate portion 52b is disposed at a position different from the first surface 51a in the Z direction. The horizontal plate portion 52b has the insertion hole 52h through which the fastening member 111 passes. The horizontal plate portion 52b is fixed to the fixing portion 82 of the metal plate 80 via the fastening member 111.

The metal plate 80 has the fixing portion 83 that protrudes from the flat surface portion 81 of the metal plate 80, is inserted into the through-hole 51h of the base plate 41, and to which the electronic component 10 is fixed. A length L1 of the standing plate portion 52a in the Z direction is larger than a length L2 of the fixing portion 83 in the Z direction.

In the present embodiment, the routing board 40 of the subunit SUY includes the base plate 41 and the bus bar 42. The flat surface portion 51 of the base plate 41 has the accommodation portion 55 that accommodates the bus bars 42. The fixing portion 52 of the base plate 41 includes a standing plate portion 52a standing in the Z direction from the flat surface portion 51, and a horizontal plate portion 52b extending in the horizontal direction from the +Z direction end of the standing plate portion 52a. The horizontal plate portion 52b is disposed at a position different from the first surface 51a in the Z direction. The horizontal plate portion 52b of the base plate 41 of the subunit SUY overlaps the base plate 41 and the horizontal plate portion 52b of the subunit SUX. The horizontal plate portion 52b of the base plate 41 of the subunit SUY has the insertion hole 52h through which the fastening member 111 passes. The horizontal plate portion 52b of the base plate 41 of the subunit SUY is fastened to the fixing portion 82 of the metal plate 80 via the fastening member 111 together with the base plate 41 and the horizontal plate portion 52b of the subunit SUX.

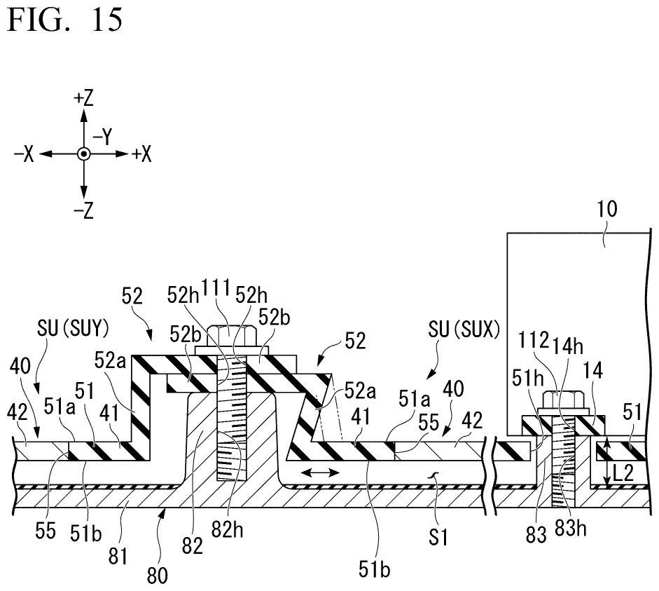

FIG. 15 is a cross-sectional view illustrating the action of the absorption structure. Here, a linear expansion coefficient of the base plate 41 made of a synthetic resin is larger than a linear expansion coefficient of the metal plate 80 made of a metal. Therefore, at the time of thermal expansion, the base plate 41 tends to extend more than the metal plate 80. On the other hand, at the time of thermal contraction, the base plate 41 tends to contract more than the metal plate 80.

In the present embodiment, the fixing portion 52 of the base plate 41 has the standing plate portion 52a. In a case where the standing plate portion 52a is provided, the standing plate portion 52a is bent in the X direction at the time of thermal expansion, so that it is possible to suppress a large load from acting on the flat surface portion 51 and/or the fixing portion 52 of the base plate 41. Similarly, at the time of thermal contraction, since the standing plate portion 52a is bent in the X direction, it is possible to suppress a large load from acting on the flat surface portion 51 and/or the fixing portion 52 of the base plate 41.

### <10. Fixing Structure Related to Plurality of Subunits>

Next, referring to FIG. 8 again, a fixing structure related to the plurality of subunits SU will be described. In the present embodiment, the main body MU is divided into a plurality of subunits SU (for example, three subunits SUX, SUY, and SUZ).

The subunit SUX includes the plurality of electronic components 10X, the base plate 41, and the plurality of bus bars 42. The plurality of bus bars 42 include portions disposed on the same plane, and are electrically connected to the plurality of electronic components 10X.

The subunit SUY includes the plurality of electronic components 10Y, the base plate 41, and the plurality of bus bars 42. The plurality of bus bars 42 include portions disposed on the same plane, and are electrically connected to the plurality of electronic components 10Y The subunit SUY is electrically connected to the subunit SUX via, for example, the coupling bus bar 75.

The subunit SUZ includes the plurality of electronic components 10Z, the base plate 41, and the plurality of bus bars 42. The plurality of bus bars 42 include portions disposed on the same plane, and are electrically connected to the plurality of electronic components 10Z. The subunit SUZ is electrically connected to the subunit SUY via, for example, a plurality of coupling bus bars 75.

In the present embodiment, each of the plurality of subunits SU (for example, three subunits SUX, SUY, and SUZ) is fixed to the metal plate 80. As a result, the plurality of subunits SU (for example, three subunits SUX, SUY, and SUZ) are integrally held by one metal plate 80.

In the present embodiment, the longitudinal direction of the subunit SUX is the X direction. The longitudinal direction of the subunit SUY is the X direction. The longitudinal direction of the subunit SUZ is the X direction. The plurality of subunits SU (for example, three subunits SUX, SUY, and SUZ) are adjacent to each other in the X direction and are arranged in a line in the X direction. The longitudinal direction of the metal plate 80 is the X direction. The length of the metal plate 80 in the X direction is larger than the sum of the lengths of the plurality of subunits SU (for example, three subunits SUX, SUY, and SUZ) in the X direction.

In the present embodiment, the fixing portion 52 of the subunit SUX and the fixing portion 52 of the subunit SUY are disposed at positions overlapping each other in the Z direction. The fixing portion 52 of the subunit SUX and the fixing portion 52 of the subunit SUY are collectively fixed to the fixing portion 82 of the metal plate 80 via one fastening member 111.

Similarly, the fixing portion 52 of the subunit SUY and the fixing portion 52 of the subunit SUZ are disposed at positions overlapping each other in the Z direction. The fixing portion 52 of the subunit SUY and the fixing portion 52 of the subunit SUZ are collectively fixed to the fixing portion 82 of the metal plate 80 by one fastening member 111.

In the present embodiment, heat generated by the electronic component 10X and the bus bar 42 included in the subunit SUX is transferred to the metal plate 80 via the one or more heat transfer members 92 facing the subunit SUX. Similarly, heat generated by the electronic component 10Y and the bus bar 42 included in the subunit SUY is transferred to the metal plate 80 via the one or more heat transfer members 92 facing the subunit SUY Heat generated by the electronic components 10Z and the bus bars 42 included in the subunit SUZ is transferred to the metal plate 80 via the one or more heat transfer members 92 facing the subunit SUZ.

In the present embodiment, the plurality of subunits SU (for example, three subunits SUX, SUY, and SUZ) may have different amounts of heat generation. Even in a case where the amounts of heat generation of the plurality of subunits SU are different, it is possible to promote cooling of the plurality of subunits SU (for example, three subunits SUX, SUY, and SUZ) by using one large metal plate 80. For example, in a case where the amounts of heat generation of the plurality of subunits SU are different, the heat of the plurality of subunits SU can be equalized by one large metal plate 80.

### <14. Advantages of Present Embodiment>

### <A. Advantages of Routing Board>

As a comparative example, an electrical connection unit in which a bus bar is disposed in a standing posture with respect to a lower wall of a housing will be considered. In such a constitution of the comparative example, it may be difficult to reduce the height of the electrical connection unit due to a width of the standing bus bar.

On the other hand, in the present embodiment, the electrical connection unit 1 includes the first electronic component 10 and the routing board 40. The routing board 40 includes the base plate 41 and the first bus bar 42. The base plate 41 has the plate-shaped flat surface portion 51 having a first surface 51a facing the first electronic component 10. The flat surface portion 51 has the first accommodation portion 55 recessed in the Z direction or penetrating the flat surface portion 51 in the Z direction. At least part of the first bus bar 42 is accommodated in the first accommodation portion 55 and extends along the flat surface portion 51. According to such a constitution, compared with the structure of the comparative example in which at least part of the routing path is formed on a plane, the bus bar is less likely to be affected in the height direction, and the height of the electrical connection unit 1 can be easily reduced.

In the present embodiment, the electrical connection unit 1 has the first connection component 20. The first connection component 20 includes a portion standing with respect to the first bus bar 42, and electrically connects the first electronic component 10 to the first bus bar 42. The first bus bar 42 has the first connection portion 61 in contact with the first connection component 20. The first connection portion 61 is accommodated in the first accommodation portion 55 and extends along the flat surface portion 51. According to such a constitution, since more portions of the routing path are formed on a plane, it is further easy to reduce the height of the electrical connection unit 1.

In the present embodiment, the electrical connection unit 1 has the second connection component 20. The second connection component 20 includes a portion standing with respect to the first bus bar 42, and electrically connects the second electronic component or an external device to the first bus bar 42. The first bus bar 42 has a second connection portion 62 in contact with the second connection component 20. The first bus bar 42 is accommodated in the first accommodation portion 55 at least over the first connection portion 61 and the second connection portion 62 and extends along the flat surface portion 51. According to such a constitution, since more portions of the routing path are formed on a plane, it is further easy to reduce the height of the electrical connection unit 1.

In the present embodiment, the first bus bar 42 has the extending portion 63 between the first connection portion 61 and the second connection portion 62. The extending portion 63 is accommodated in the first accommodation portion 55, passes through the region R overlapping the electronic component 10 when viewed from the Z direction, and extends over both sides of the region R. According to such a constitution, since the extending portion 63 is accommodated in the first accommodation portion 55, it is difficult to be restricted in the routing layout due to the presence of the electronic component 10. Thus, for example, it is possible to achieve a routing layout that makes electrical characteristics more advantageous, such as making it easier to cause the extending portion 63 to linearly extend. In addition, routing of the bus bar around the electronic component 10 can be avoided. This makes it possible to improve the electrical characteristics of the electrical connection unit 1 and/or to reduce the size of the electrical connection unit 1.

In the present embodiment, the first bus bar 42 extends to the region R overlapping the first electronic component 10 when viewed from the Z direction, and has the extension 64 having the end 42e1 at a position overlapping the first electronic component 10. The extension 64 is accommodated in the first accommodation portion 55 and extends along the flat surface portion 51. According to this constitution, since the extension 64 is accommodated in the first accommodation portion 55, the height of the electrical connection unit 1 can be reduced, and a metallic heat dissipation portion (extension 64) for promoting heat dissipation and/or heat storage of the first electronic component 10 can be disposed below the first electronic component 10. As a result, it is possible to improve the heat dissipation property and/or the heat storage property of the electrical connection unit 1.

In the present embodiment, the first bus bar 42 is accommodated in the first accommodation portion 55 over the entire length of the first bus bar 42 and extends along the flat surface portion 51. According to such a constitution, since more portions of the routing path are formed on a plane, it is further easy to reduce the height of the electrical connection unit 1.

In the present embodiment, the electrical connection unit 1 includes the second bus bar 42 electrically connected to the second terminal 13B of the first electronic component 10. The flat surface portion 51 has the second accommodation portion 55 recessed in the Z direction or penetrating the flat surface portion 51 in the Z direction at a position away from the first accommodation portion 55. At least part of the second bus bar 42 is accommodated in the second accommodation portion 55 and extends along the flat surface portion 51. According to such a constitution, since more portions of the routing path including the plurality of bus bars 42 are held on a plane by one base plate 41, it becomes easier to reduce the height of the electrical connection unit 1.

In the present embodiment, the electrical connection unit 1 includes the third bus bar 42. The first bus bar 42 is a bus bar included in the positive electrode line PL. The third bus bar 42 is a bus bar included in the negative electrode line NL. The flat surface portion 51 has the third accommodation portion 55 recessed in the Z direction or penetrating the flat surface portion 51 in the Z direction at a position away from the first accommodation portion 55. At least part of the third bus bar 42 is accommodated in the third accommodation portion 55 and extends along the flat surface portion 51. According to such a constitution, since more portions of the routing path forming the positive electrode line PL and the negative electrode line NL are held on a plane by one base plate 41, it becomes easier to reduce the height of the electrical connection unit 1.

In the present embodiment, the electrical connection unit 1 includes the fourth bus bar 42G, the fifth bus bar 75D, and the third connection component 100 that electrically connects the fourth bus bar 42G to the fifth bus bar 75D. The flat surface portion 51 has the fourth accommodation portion 55 recessed in the Z direction or penetrating the flat surface portion 51 in the Z direction at a position away from the first accommodation portion 55. At least part of the fourth bus bar 42G is accommodated in the fourth accommodation portion 55 and extends along the flat surface portion 51. The third connection component 100 includes a portion standing with respect to the fourth bus bar 42G. The fifth bus bar 75D is supported by the third connection component 100 at a position away from the first bus bar 42 in the Z direction, and extends in parallel with the first surface 51a. According to such a constitution, a three-dimensional routing path can be easily formed by the fourth bus bar 42G, the third connection component 100, and the fifth bus bar 75D. Thus, the electrical connection unit 1 having excellent assemblability can be provided. In addition, since the fourth bus bar 42G is disposed in the accommodation portion 55 of the base plate 41, part of the three-dimensional routing path is formed within the thickness of the base plate 41. As a result, it becomes easier to reduce the height of the electrical connection unit 1.

In the present embodiment, the fifth bus bar 75D extends to straddle the first bus bar 42 at a position away from the first bus bar 42 in the Z direction. According to such a constitution, it is easy to form a routing path that three-dimensionally intersects the first bus bar 42 by using the third connection component 100 and the fifth bus bar 75D. Thus, the electrical connection unit 1 having excellent assemblability can be provided.

### <B. Advantages of Flat Bus Bars>

As a comparative example, an electrical connection unit in which a bus bar is disposed in a standing posture with respect to a lower wall of a housing will be considered. In such a constitution of the comparative example, it is necessary to fix the bus bar to the housing in a standing posture, and it is difficult to improve workability regarding attachment of the bus bar. In this case, it may be difficult to improve the assemblability of the electrical connection unit 1.

On the other hand, in the present embodiment, the electrical connection unit 1 includes the base plate 41 and the bus bar 42. The base plate 41 includes the flat surface portion 51 having a plate shape. The flat surface portion 51 has the first accommodation portion 55 recessed in the Z direction or penetrating the flat surface portion 51 in the Z direction. At least part of the bus bar 42 is accommodated in the first accommodation portion 55 and extends along the flat surface portion 51. According to such a constitution, the base plate 41 and the bus bar 42 can be easily handled integrally, and workability regarding attachment of the bus bar can be improved compared with the constitution of the comparative example. Thus, the assemblability of the electrical connection unit 1 can be improved.

In the present embodiment, the bus bar 42 is accommodated in the accommodation portion 55 over the entire length of the bus bar 42 and extends along the flat surface portion 51. According to such a constitution, it is easy to reduce the height of the electrical connection unit 1 while improving the assemblability of the electrical connection unit 1.

In the present embodiment, the bus bar 42 is integrated with the base plate 41 through insert molding. According to such a constitution, it is possible to eliminate or reduce the work of manually attaching the bus bar 42 to the housing. Thus, the assemblability of the electrical connection unit 1 can be further improved.

In the present embodiment, the fastening member 43 protruding from the bus bar 42 in the Z direction and the connection components 20 and 30 attached to the fastening member 43 from the Z direction are provided. The connection components 20 and 30 electrically connect the electronic component 10 or an external device to the bus bar 42. According to such a constitution, a direction of work of attaching a connection target component to the bus bar 42 can be easily aligned with the Z direction. In a case where the direction of work can be aligned, the assemblability of the electrical connection unit 1 can be further improved.

In the present embodiment, the connection component 20 is connected to the electronic component 10 from the X direction (or the Y direction). According to such a constitution, a connection direction of the electronic component 10 with respect to the bus bar 42 can be converted into the Z direction by using the connection component 20 for the electronic component 10 that needs to be connected from the X direction. Thus, the assemblability of the electrical connection unit 1 can be further improved.

### <C. Advantages of Exposure Structure on Upper Surface Side of Bus Bar>

As a comparative example, an electrical connection unit in which the upper surface side of the bus bar 42 is covered with a synthetic resin will be considered. In such a constitution of the comparative example, it is difficult to improve the heat dissipation property of the bus bar 42.

On the other hand, in the present embodiment, the electrical connection unit 1 includes the first electronic component 10 and the routing board 40. The routing board 40 includes a base plate 41 and a bus bar 42. The base plate 41 has the plate-shaped flat surface portion 51 having the first surface 51a facing the first electronic component 10 and the second surface 51b located on the side opposite to the first surface 51a. The flat surface portion 51 has the accommodation portion 55 recessed in the Z direction or penetrating the flat surface portion 51 in the Z direction. At least part of the bus bar 42 has the plate portion 42p that is accommodated in the accommodation portion 55 and extends along the flat surface portion 51. The plate portion 42p includes the first connection portion 61 overlapping the first connection component 20 when viewed in the Z direction, and the extending portion 63 extending from the first connection portion 61 in a direction intersecting the Z direction. At least part of the extending portion 63 is exposed to the outside of the base plate 41 on the first surface 51a side. According to such a constitution, at least part of a portion of the bus bar 42 other than the connection portions 61 and 62 connected to other components is exposed to the outside and functions as an area for releasing heat. In this case, the heat dissipation property of the electrical connection unit 1 can be improved.

In the present embodiment, the extending portion 63 is exposed to the outside of the base plate 41 on the first surface 51a side at least in part of the region R overlapping the first connection component 20 when viewed from the Z direction. According to such a constitution, it is easy for part of the extending portion 63 to function as a heat dissipation portion that transfers heat from the first connection component 20. In this case, the heat dissipation property of the electrical connection unit 1 can be improved.

In the present embodiment, the first bus bar 42 has the second connection portion 62 overlapping the second connection components 20 and 30 when viewed in the Z direction. The first bus bar 42 is accommodated in the accommodation portion 55 at least over the entire length between the first connection portion 61 and the second connection portion 62, extends along the flat surface portion 51, and is exposed to the outside of the base plate 41 on the first surface 51a side. According to such a constitution, since the wider portion functions as a heat dissipation area, the heat dissipation property of the electrical connection unit 1 can be further improved.

In the present embodiment, the bus bar 42 is accommodated in the accommodation portion 55 over the entire length of the bus bar 42, extends along the flat surface portion 51, and is exposed to the outside of the base plate 41 on the first surface 51a side. According to such a constitution, since the wider portion functions as a heat dissipation area, the heat dissipation property of the electrical connection unit 1 can be further improved.

At least part of the extending portion 63 is exposed to the outside of the base plate 41 not only on the first surface 51a side but also on the second surface 51b side. According to such a constitution, since the wider portion functions as a heat dissipation area, the heat dissipation property of the electrical connection unit 1 can be further improved.

In the modification example of the present embodiment, the electrical connection unit 1 includes the metal plate 80 facing the flat surface portion 51 with the gap S1 between the metal plate 80 and the flat surface portion 51, and the heat transfer member 92 disposed between the bus bar 42 and the metal plate 80. The base plate 41 includes a cover portion 51v that covers at least part of the extending portion 63 on the second surface 51b side. According to such a constitution, even in a case where heat is likely to be confined in the gap S1 between the base plate 41 and the metal plate 80, it is possible to suppress the heat from being easily confined in the gap S1 by providing the cover portion 51v.

### <D. Advantages of Exposure Structure on Lower Surface Side of Bus Bar>

In order to improve the holding property of the bus bar 42, a structure in which a portion other than the connection surface of the bus bar 42 with the electronic component 10 and the like is covered with a resin may be adopted. However, in the structure in which the portion other than the connection surface of the bus bar 42 is covered, there is a problem that the heat dissipation property of the bus bar 42 deteriorates. In the present embodiment, the lower surface (a surface opposite to the component mounting surface) of the bus bar 42 is exposed, and the heat transfer sheet is set on this exposed surface. The heat transfer sheet is connected to the metal plate 80 (a rigid member or a heat dissipation member) provided below the routing board 40. As a result, heat can be favorably transferred from the bus bar 42 to the metal plate 80 (to the side opposite to the component mounting surface) via the heat transfer sheet.

### <E. Advantages of Fixing Structure of Subunit SU>

In the present embodiment, a plurality of circuit constitution bodies SUX, SUY, and SUZ, and a support member (metal plate 80) that supports the plurality of circuit constitution bodies SUX, SUY, and SUZ on a support surface (the upper surface 81a of the flat surface portion 81) are provided. Each of the circuit constitution bodies SUX, SUY, and SUZ includes an electronic component 10 constituting a circuit, and a mounting member (routing board 40) that is disposed along the support surface and mounts the electronic component 10 in a circuit component mounting region 51d formed on a component mounting surface (the upper surface 51c of the flat surface portion 51) opposite to the metal plate 80. The routing board 40 is fixed to the metal plate 80 via a plurality of fixing portions 52 and 82 disposed to surround an outer side of the circuit component mounting region 51d when viewed from a normal direction of the support surface.

According to such a constitution, the routing board 40 of each of the circuit constitution bodies SUX, SUY, and SUZ is fixed to the metal plate 80 via the plurality of fixing portions 52 and 82 that are disposed to surround the outer side of the circuit component mounting region 51d, so that it is possible to curb the strain between the metal plate 80 and the routing board 40 due to heat generation of any of the circuit constitution bodies from acting on the other circuit constitution bodies.

That is, when the resin routing board 40 expands/contracts with respect to the metal plate 80 at a high temperature/low temperature of each of the circuit constitution bodies SUX, SUY, and SUZ, a difference occurs in a length (pitch) between a plurality of fixing positions between the metal member (rigid member) and the resin member (bus bar insert plate). Such repeated expansion/contraction of the resin member may damage the vicinity of the fixing portion of the bus bar insert plate.

In the present embodiment, the fixing portion 52 of the bus bar insert plate (routing board 40) is provided at a height different from that of the main body (the flat surface portion 51 forming the component mounting surface), and is fixed to the boss (the fixing portion 82) of the metal plate 80. As a result, the thermal expansion/contraction of the bus bar insert plate can be absorbed by the deflection of the standing plate portion (standing wall portion) 52a. The standing plate portion 52a is located closer to the circuit component mounting region 51d than the boss (fixing portion 82) of the metal plate 80, and can insulate the fixing portion (boss) 82 from the bus bar 42 around the fixing portion.

In the present embodiment, the metal plate 80 is an integrated metal member, and the routing boards 40 of the respective circuit constitution bodies SUX, SUY, and SUZ include resin base plates 41 that are separate from each other.

According to such a constitution, it is possible to curb the strain between the metallic support member (metal plate 80) and the resin base member (base plate 41) of the mounting member due to the heat generation of any of the circuit constitution bodies SUX, SUY, and SUZ from acting on the other circuit constitution bodies.

In the present embodiment, each of the fixing portions 52 and 82 includes a columnar boss (fixing portion 82) protruding in the normal direction from the support surface of the metal plate 80 and a three-dimensional structure portion (fixing portion 52) protruding in the normal direction from the component mounting surface of the routing board 40, and the three-dimensional structure portion (fixing portion 52) includes a standing plate portion 52a rising in the normal direction from the component mounting surface of the routing board 40 and an (upper plate portion) 52b extending in parallel with the component mounting surface from a tip of the standing plate portion 52a and fixed to a tip of the boss 82.

According to such a constitution, since the upper plate portion 52b of the fixing portion 52 made of a resin is supported via the standing plate portion 52a and the upper plate portion 52b is fixed to the boss 82 made of a metal, the standing plate portion 52a is bent in the direction along the surface of the component mounting surface at the time of thermal expansion/contraction of the routing board 40, and it is possible to curb a large load from acting on the flat surface portion 51 of the routing board 40.

In the present embodiment, the fixing portion 82 between the pair of circuit constitution bodies adjacent to each other on the support surface is shared for fixing the pair of circuit constitution bodies.

According to such a constitution, by sharing the fixing portion 82 between the pair of adjacent circuit constitution bodies for fixing the pair of circuit constitution bodies, it is possible to simplify the fixing structure of the plurality of circuit constitution bodies and reduce the cost.

In the present embodiment, when viewed from the normal direction of the support surface, the circuit component mounting region 51d has a rectangular shape, and the fixing portions 52 and 82 are disposed at each top portion of the rectangular shape of the circuit component mounting region 51d.

According to such a constitution, by disposing the fixing portions 52 and 82 at the four corners of the circuit component mounting region 51d having a rectangular shape in a plan view, the circuit component mounting region 51d can be efficiently secured.

### MODIFICATION EXAMPLES

Next, several modification examples will be described. Note that a constitution other than that described below in each modification example is the same as the constitution of the above-described embodiment.

### First Modification Example

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### Second Modification Example

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The base plate 41 of the routing board 40 may include a plurality of members (plate members or sheet members). The plurality of members are provided to sandwich the plurality of bus bars 42 arranged in the horizontal direction, for example, from both sides in the Z direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed. For example, in this case, the accommodation portion 55 formed between the plurality of members corresponds to an example of an “accommodation portion recessed in the first direction (Z direction)”.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiment and the modification examples are not limited to the examples described above. For example, a plurality of embodiments may be implemented in combination with each other. The above-described embodiments can be implemented in various other forms, and various additions, omissions, substitutions, and changes can be made without departing from the concept of the present disclosure.

### INDUSTRIAL APPLICABILITY

According to the present disclosure, thermal characteristics of the electrical connection unit can be improved.

### REFERENCE SIGNS LIST

1 Electrical connection unit
10 Electronic component
40 Routing board (mounting member)
41 Base plate (base member, resin member)
42 Bus bar
51 Flat surface portion
51c Upper surface (component mounting surface, base surface)
51d Component mounting region
52 Fixing portion (three-dimensional structure portion)
52a Standing plate portion
52b Upper plate portion
80 Metal plate (support member, metal member)
81 Flat surface portion
81a Upper surface (support surface)
82 Fixing portion (boss)
SU, SUX, SUY, SUZ Subunit (circuit constitution body)

What is claimed is:

1. An electrical connection unit comprising:
a plurality of circuit constitution bodies; and
a support member that supports the plurality of circuit constitution bodies, wherein
each of the circuit constitution bodies includes
a plurality of electronic components,
a bus bar that electrically connects the plurality of electronic components, and
an insulating base member that holds the bus bar, and
in a case where a direction in which the plurality of electronic components and the base member face each other is a first direction, the base member has a facing region facing the plurality of electronic components when viewed from the first direction, and is fixed to the support member via a plurality of fixing portions that are disposed to surround an outer side of the facing region when viewed from the first direction.

2. The electrical connection unit according to claim 1, wherein
the plurality of circuit constitution bodies include a first circuit constitution body and a second circuit constitution body disposed adjacent to the first circuit constitution body, and
the first circuit constitution body and the second circuit constitution body have different heat generation timings.

3. The electrical connection unit according to claim 1, wherein
the support member is one metal plate, and
the base member is a separate synthetic resin member.

4. The electrical connection unit according to claim 3, wherein
the base member has a base surface including the facing region,
each of the fixing portions includes
a first fixing portion protruding from the support member in the first direction, and
a second fixing portion protruding from the base surface of the base member, and
the second fixing portion includes a first portion rising from the base surface in the first direction, and a second portion extending from a tip of the first portion in parallel with the base surface and fixed to the first fixing portion.

5. The electrical connection unit according to claim 1, wherein
the plurality of circuit constitution bodies include a first circuit constitution body and a second circuit constitution body disposed adjacent to the first circuit constitution body, and
the plurality of fixing portions include a fixing portion disposed at a boundary between the first circuit constitution body and the second circuit constitution body and shared for fixing the first circuit constitution body and the second circuit constitution body.

6. The electrical connection unit according to claim 1, wherein
the facing region has a rectangular shape when viewed from the first direction, and the plurality of fixing portions are disposed to correspond to four corner portions of the facing region.
